(19) United States
(12) Patent Application Publication
(10) Pub. No.: US 2025/0036572 A1
(43) Pub. Date: Jan. 30, 2025

(54) METHOD AND ELECTRONIC CIRCUIT FOR MEMORY REPLACEMENT

(71) Applicant: KOREA ADVANCED INSTITUTE OF SCIENCE AND TECHNOLOGY, Daejeon (KR)

(72) Inventors: Shinhyun CHOI, Daejeon (KR); Myoungsoo Jung, Daejeon (KR); Hakcheon Jeong, Daejeon (KR); See-On Park, Daejeon (KR); Donghyun Gouk, Daejeon (KR); Seonghyeon Jang, Daejeon (KR)

(73) Assignee: KOREA ADVANCED INSTITUTE OF SCIENCE AND TECHNOLOGY, Daejeon (KR)

(21) Appl. No.: 18/511,301

(22) Filed: Nov. 16, 2023

(30) Foreign Application Priority Data
Jul. 27, 2023 (KR) 10-2023-0098439

(51) Int. Cl. G06F 12/12; G06F 12/0864

(52) U.S. Cl. CPC G06F 12/12; G06F 12/0864

(57) ABSTRACT

A method and electronic circuit for memory replacement are provided. The method for memory replacement includes generating an input signal in response to an event for a memory, providing the input signal to a time-varying circuit including a plurality of time-varying devices, generating an output signal by reading a value stored in at least one time-varying device among the plurality of time-varying devices, and determining a storage space for replacement, based on the output signal.

### CROSS-REFERENCE TO RELATED APPLICATION

This application is based on and claims priority under 35 U.S.C. § 119 to Korean Patent Application No. 10-2023-0098439, filed on Jul. 27, 2023, in the Korean Intellectual Property Office, the disclosure of which is incorporated by reference herein in its entirety.

### BACKGROUND

### 1. Field

The disclosure relates to a method and electronic circuit for memory replacement. More particularly, the disclosure relates to a method and electronic circuit for determining a storage space for replacement in a memory by using a time-varying device.

### 2. Description of the Related Art

In a system in which a processor and a memory are separated, the memory stores data, and the processor loads and processes the data stored in the memory and then stores the data back in the memory. To reduce delay caused due to a speed difference between the processor and the memory, the system uses a memory hierarchy.

In the memory hierarchy, the speed of the memory speed increases at a higher level and decreases at lower level. The processor first accesses a high level memory. When the data the processor is looking for is not stored in the high level memory, data is searched for from a low level memory. Data found in the search is transferred from the low level memory to the high level memory.

Data transfer between memory levels needs a memory replacement algorithm for determining which storage space of the memory is used to store the transferred data. There are various known memory replacement algorithms, and there are various circuits for implementing the memory replacement algorithms.

As the size of memory increases, memory replacement algorithms become more complex. In the art, circuits for implementing memory replacement algorithms have a problem in that scalability is low because their physical sizes and energy consumption increase exponentially as the memory size increases.

### SUMMARY

Provided is a method and electronic circuit for memory replacement.

Additional aspects will be set forth in part in the description which follows and, in part, will be apparent from the description, or may be learned by practice of the presented embodiments of the disclosure.

According to an embodiment of the disclosure, a method for memory replacement includes
generating an input signal in response to an event for a memory, providing the input signal to a time-varying circuit including a plurality of time-varying devices that correspond to a plurality of storage spaces of the memory and store values that change with time, generating an output signal by reading a value stored in at least one time-varying device among the plurality of time-varying devices, and determining a storage space for replacement from among the plurality of storage spaces of the memory, based on the output signal.

The generating of the input signal may include generating a different input signal according to the type of event for the memory.

The generating of the input signal may include generating a first input signal when the event for the memory is an event in which a storage space for replacement in the memory does not need to be determined, and generating a second input signal when the event for the memory is an event in which a storage space for replacement in the memory needs to be determined.

A magnitude of the first input signal may be greater than a magnitude of the second input signal.

The event in which the storage space for replacement in the memory does not need to be determined may include at least one of an event in which a processor accesses data stored in the memory, an event in which a memory of a high level accesses the data stored in the memory, and an event of replacing a storage space determined in the determining of the storage space for replacement in the memory.

The event in which the storage space for replacement in the memory needs to be determined may include at least one of an event in which a processor needs data not stored in the memory and an event in which a memory of a high level needs the data not stored in the memory.

The providing of the input signal to the time-varying circuit may include providing the input signal to the time-varying circuit such that a value stored in at least one time-varying device among the plurality of time-varying devices is changed.

The providing of the input signal to the time-varying circuit may include providing the input signal to the time-varying circuit such that the value stored in at least one time-varying device among the plurality of time-varying devices is read.

The providing of the input signal to the time-varying circuit may include providing the input signal to a time-varying device corresponding to a storage space related to the event among the plurality of storage spaces of the memory, from among the plurality of time-varying devices.

The generating of the output signal may include generating the output signal by reading values stored in two or more time-varying devices corresponding to two or more storage spaces related to the event among the plurality of storage spaces of the memory, from among the plurality of time-varying devices.

The determining of the storage space for replacement may include selecting one time-varying device from among the two or more time-varying devices by analyzing, based on the output signal, the values stored in the two or more time-varying devices, and determining a storage space corresponding to the selected time-varying device from among the two or more storage spaces as the storage space for replacement.

The selecting of the one time-varying device from among the two or more time-varying devices may include selecting one time-varying device storing a value less than a predetermined value from among the two or more time-varying devices, based on the output signal.

The selecting of the one time-varying device from among the two or more time-varying device may include selecting one time-varying device storing a smallest value from among the two or more time-varying devices, based on the output signal.

The generating of the output signal may include generating the output signal by reading the value stored in the at least one time-varying element, when the event is an event in which a storage space for replacement in the memory needs to be determined.

The memory may include at least one of a register, a cache, and a main memory.

Each of the plurality of time-varying devices may include at least one of a memristor, dynamic random-access memory (DRAM), and static random-access memory (SRAM).

According to an embodiment of the disclosure, an electronic circuit for memory replacement includes
an input circuit configured to generate an input signal in response to an event for a memory, a time-varying circuit configured to receive the input signal, and including a plurality of time-varying devices that correspond to a plurality of storage spaces of the memory and store values that change with time, an output circuit configured to generate an output signal by reading a value stored in at least one time-varying device among the plurality of time-varying devices, and a controller configured to determine a storage space for replacement from among the plurality of storage spaces of the memory, based on the output signal.

The memory may include at least one of a register, a cache memory, and a main memory.

Each of the plurality of time-varying devices may include at least one of a memristor, DRAM, and SRAM.

Each of the plurality of time-varying devices may be configured to increase a stored value as an input signal generated in response to an event in which a storage space for replacement in the memory needs to be determined is provided.

According to an embodiment of the disclosure, a method for replacing a set-associative cache includes generating an input signal in response to an event for the set-associative cache, providing the input signal to a time-varying circuit including an array of time-varying devices that correspond to a plurality of lines of the set-associative cache and store values that change with time, generating an output signal by reading a value stored in at least one time-varying device in the array of time-varying devices, and determining a line for replacement from among the plurality of lines of the set-associative cache, based on the output signal.

The providing of the input signal to the time-varying circuit may include selecting a row and a column of the array of time-varying devices, based on an index and a way of a line related to the event from among the plurality of lines, and providing the input signal to a time-varying device in the selected row and the selected column in the array of time-varying devices.

The selecting of the row and the column of the array of time-varying devices may include selecting a row of the array of time-varying devices corresponding to the index of the line related to the event, and selecting a column of the array of time-varying devices corresponding to the way of the line related to the event.

The generating of the output signal may include generating the output signal by reading values stored in time-varying devices in one row in the array of time-varying devices.

The generating of the output signal may include selecting a row of the array of time-varying devices, based on an index of lines related to the event from among the plurality of lines, and generating the output signal by reading values stored in time-varying devices in the selected row in the array of time-varying devices.

The determining of the line for replacement may include selecting one time-varying device from among time-varying devices in the selected row by analyzing, based on the output signal, values stored in the time-varying devices in the selected row, and determining, as the line for replacement, a line of a way corresponding to a column of the selected time-varying device from among the lines related to the event.

### BRIEF DESCRIPTION OF THE DRAWINGS

The above and other aspects, features, and advantages of certain embodiments of the inventive concept will be more apparent from the following description taken in conjunction with the accompanying drawings, in which:

FIGS. 1A through 1D are block diagrams of electronic devices according to embodiments;

FIG. 2 is a block diagram of an electronic circuit for memory replacement, according to an embodiment;

FIGS. 3A through 3D illustrate time-varying devices according to embodiments;

FIGS. 4A and 4B are graphs showing input signals according to embodiments;

FIG. 5A is a diagram illustrating correspondence between storage spaces and time-varying devices, according to an embodiment;

FIG. 5B is a diagram illustrating an operation of changing a value stored in a time-varying device and an operation of reading the value stored in the time-varying device, according to an embodiment;

FIG. 6 is a flowchart of a method for memory replacement, according to an embodiment;

FIG. 7 is a flowchart of an operation method of an electronic circuit for memory replacement, according to an embodiment;

FIG. 8A is a diagram illustrating an address and a set-associative cache, according to an embodiment;

FIG. 8B is a diagram illustrating a correspondence between a set-associative cache and time-varying elements, according to an embodiment;

FIG. 8C is a diagram illustrating replacement of a line of a set-associative cache, according to an embodiment;

FIG. 8D is a diagram illustrating a correspondence between a set-associative cache and time-varying devices, according to an embodiment;

FIG. 9 is a flowchart of a method for replacing a set-associative cache, according to an embodiment;

FIG. 10A is a graph showing a value stored in a time-varying device, according to an embodiment; and

FIG. 10B is a graph showing values stored in time-varying devices, according to an embodiment.

### DETAILED DESCRIPTION

Throughout the disclosure, the expression “at least one of a, b or c” indicates only a, only b, only c, both a and b, both a and c, both b and c, all of a, b, and c, or variations thereof.

In the disclosure, in a relationship with a memory, an “upper level memory” refers to a memory of a higher level than the memory, and a “low level memory” refers to a memory of a lower level than the memory.

Various embodiments of the disclosure will be described below with reference to the accompanying drawings.

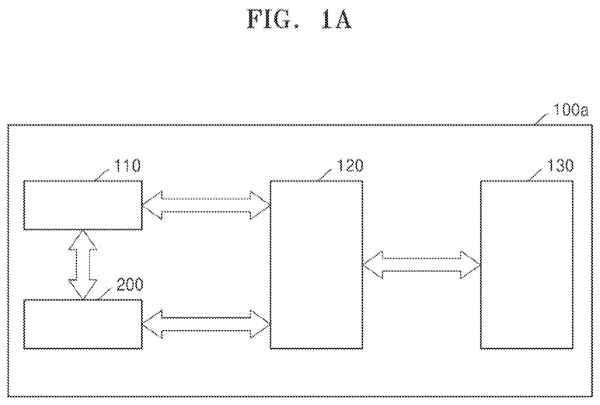

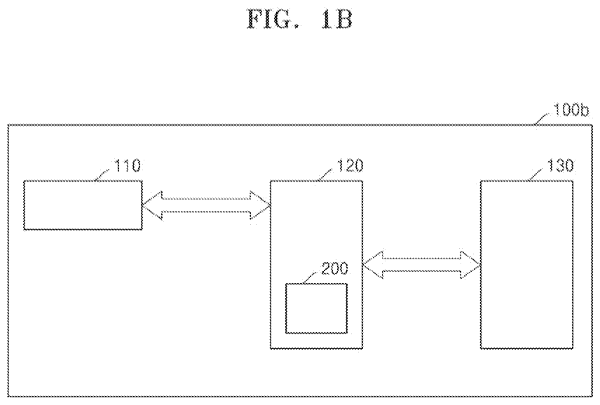

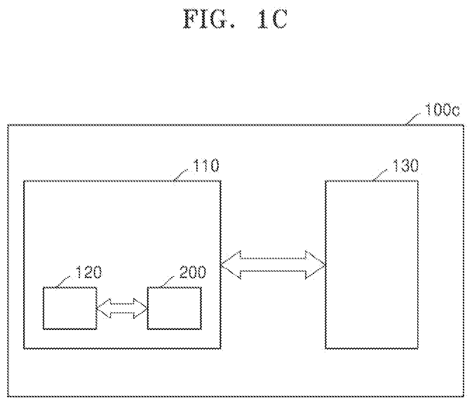

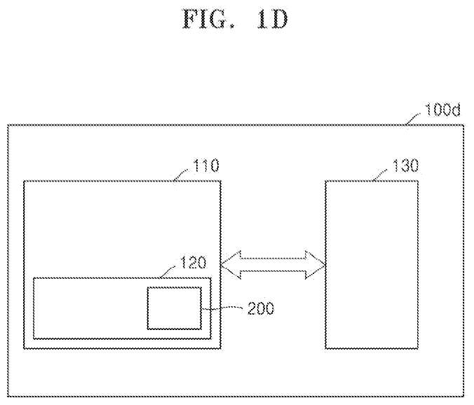

FIG. 1A is a block diagram of an electronic device 100a according to an embodiment.

The electronic device 100a may be any type of device including first and second memories 120 and 130 of a hierarchical structure and a processor 110 for processing data read from the first and second memories 120 and 130. For example, the electronic device 100a may include, but is not limited to, a personal computer (PC), a laptop, a tablet, a smartphone, a mobile phone, a personal digital assistant (PDA), a wearable device, a digital camera, a home appliance, a medical device, a drone, an airplane, an automobile, or a system on chip (SoC) mounted on the listed examples.

The electronic device 100a according to an embodiment includes the processor 110, the first memory 120, the second memory 130, and an electronic circuit 200. The processor 110, the first memory 120, the second memory 130, and the electronic circuit 200 may communicate with one another through a bus.

The processor 110 is a circuit configured to perform instructions. For example, the processor 110 may be a circuit including an arithmetic and logical unit (ALU) or a floating-point unit (FPU). For example, the processors 110 may be, but is not limited to, a central processing unit (CPU), a graphics processing unit (GPU), a neural processing unit (NPU), a tensor processing unit (TPU), a digital signal processor (DSP), or an application processing unit (APU).

Each of the first and second memories 120 and 130 may be any type of memory including flip-flop (FF)-based storage spaces, latch-based storage spaces, capacitor-based storage spaces, metal oxide semiconductor field effect transistor (MOSFET)-based storage spaces, MOSFET-based storage spaces with a floating gate, magnetism-based storage spaces, phase change material-based storage spaces, magnetic tunnel junction (MTJ)-based storage spaces, or metal oxide-based storage spaces.

Each of the first and second memories 120 and 130 may be, but is not limited to, one of a register, a cache, a set associative cache, a main memory, a flash memory, and a hard disk. Each of the first and second memories 120 and 130 may be, but is not limited to, one of a memory buffer register (MBR), an L1 cache, an L2 cache, an L3 cache, a last level (LL) cache, SRAM, DRAM, phase change random access memory (PRAM), magnetic random access memory (MRAM), resistive random access memory (ReRAM), ferroelectrics random access memory (FRAM), a solid-state drive (SSD), and a hard disk drive (HDD).

The first and second memories 120 and 130 may establish a memory hierarchy. In the memory hierarchy, the first memory 120 may be a higher level memory than the second memory 130. For example, the first memory 120 may be a register, and the second memory 130 may be a cache. Alternatively, the first memory 120 may be an L2 cache, and the second memory 130 may be an L3 cache. Alternatively, the first memory 120 may be a cache, and the second memory 130 may be a main memory. If only the condition that the first memory 120 is a higher-level memory than the second memory 130 is satisfied, various combinations of memories may be used as the first and second memories 120 and 130.

The processor 110 may access the data of the first memory 120. The processor 110 may read data from the first memory 120 or may store data in the first memory 120. When the data sought by the processor 110 is not stored in the first memory 120 but stored in the second memory 130, data may be transmitted from the second memory 130 to the first memory 120.

Operations in which the first memory 120 exchanges data with the processor 110 and the second memory 130 may be performed. Among the operations, replacement of the storage space of the first memory 120 may be requested. For example, when data is stored in all of the storage spaces of the first memory 120 and data of the second memory 130 needs to be stored in the first memory 120, the storage space of the first memory 120 needs to be replaced.

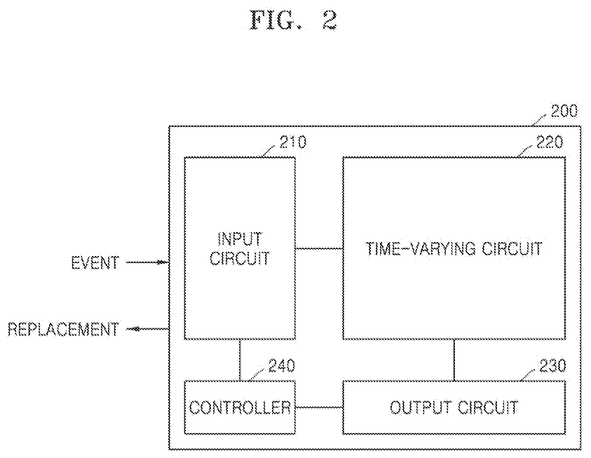

The electronic circuit 200 is configured to determine a storage space for replacement among the storage spaces of the first memory 120. When the storage space for replacement is determined by the electronic circuit 200, data in the determined storage space may be replaced. A detailed description of the electronic circuit 200 will be described later with reference to FIG. 2 and its subsequent drawings.

In the electronic device 100a according to the embodiment of FIG. 1A, the first memory 120, the second memory 130, and the electronic circuit 200 are disposed outside the processor 110.

FIGS. 1B through 1D are block diagrams illustrating electronic devices 100b, 100c, and 100d according to embodiments. FIGS. 1B through 1D show various arrangements of the processor 110, the first memory 120, the second memory 130, and the electronic circuit 200.

Referring to FIG. 1B, the electronic circuit 200 may be disposed inside the first memory 120. In this case, a communication time between the first memory 120 and the electronic circuit 200 may be reduced.

Referring to FIGS. 1C and 1D, the first memory 120 and the electronic circuit 200 may be disposed inside the first memory 110. The electronic circuit 200 may be disposed outside the first memory 120 as shown in FIG. 1C, or may be disposed inside the first memory 120 as shown in FIG. 1D.

A layout of the processor 110, the first memory 120, the second memory 130, and the electronic circuit 200 is not limited by FIGS. 1A through 1D, and various layouts are possible.

FIG. 2 is a block diagram of an electronic device 200 according to an embodiment.

The electronic circuit 200 is configured to select a storage space for replacement in a memory, based on a time-varying circuit 220. The electronic circuit 200 receives information of an event for the memory. The information of the event may include information about occurrence of the event for the memory or information about the type of the event for the memory. The electronic circuit 200 updates the time-varying circuit 220 or reads a value stored in the time-varying circuit 220, according to an event. The electronic circuit 200 determines the storage space for replacement in the memory, based on the values stored in the time-varying circuit 220.

The electronic circuit 200 according to an embodiment includes an input circuit 210, a time-varying circuit 220, an output circuit 230, and a controller 240.

The input circuit 210 may generate an input signal in response to the event for the memory. The event for the memory includes operations related to a memory according to instructions of a process performed by an electronic device. For example, the event for the memory may be, but is not limited to, an event in which a processor accesses the memory, an event in which a high level memory accesses the memory, an event in which the memory accesses a low level memory, or an event of requiring replacement of the storage space of the memory.

The input circuit 210 may generate input signals having different magnitudes according to the type of the event for the memory. The input circuit 210 may include a voltage selecting circuit configured to generate voltage signals having different magnitudes according to the type of event.

For example, the input circuit 210 may generate a small input signal in response to an event in which a storage space for replacement in the memory needs to be determined, and may generate a large input signal in response to the other events. Alternatively, the input circuit 210 may generate a large input signal in response to the event in which the processor accesses the memory and the event in which the upper level memory accesses the memory, and may generate a small input signal in response to the event in which the memory accesses the low level memory.

An input signal generated by the input circuit 210 may be a pulse signal. To this end, the input circuit 210 may include a pulse generating circuit.

The input circuit 210 may provide the input signal to the time-varying circuit 220. The time-varying circuit 220 includes a plurality of time-varying devices whose stored values change over time. The input signal provided to the time-varying circuit 220 may be used to change the value stored in the time-varying device. Alternatively, the input signal provided to the time-varying circuit 220 may be used to read a value stored in the time-varying device.

In the time-varying circuit 220, the plurality of time-varying devices may be arranged in an array. Accordingly, the input circuit 210 may include a row driver for applying an input signal to a row of the array of time-varying devices and/or a column driver for applying an input signal to a column of the array of time-varying devices.

The input circuit 210 may generate different input signals according to the type of the event for the memory. For example, the input circuit 210 may generate an input signal for reading a value stored in the time-varying circuit 220, in response to an event in which a storage space for replacement in the memory needs to be determined. Alternatively, the input circuit 210 may generate an input signal for changing the value stored in the time-varying circuit 220, in response to an event in which a storage space for replacement in the memory does not need to be determined.

A value stored in a time-varying device may increase according to an applied input signal. According to the magnitudes and number of input signals, an increment in the value stored in the time-varying device may change. When a small input signal is applied, the value stored in the time-varying device may increase slightly, and, when a large input signal is applied, the value stored in the time-varying device may increase significantly. When an input signal is applied a relatively small number of times within a certain time period, the value stored in the time-varying device may increase slightly, and, when an input signal is applied a relatively large number of times within the certain time period, the value stored in the time-varying device may increase significantly.

A time-varying device of the time-varying circuit 220 may correspond to the storage space of a memory. One time-varying device may correspond to one or more storage spaces. For example, one time-varying device may correspond to one storage space, or one time-varying device may correspond to two or more storage spaces.

An input signal may be provided to a time-varying device corresponding to a storage space related to an event. For example, when an event in which a processor accesses a specific storage space among a plurality of storage spaces of a memory occurs, an input signal may be provided to a specific time-varying device corresponding to the specific storage space. Alternatively, when an event in which specific storage spaces among a plurality of storage spaces of a memory need to be replaced occurs, an input signal may be provided to specific time-varying devices corresponding to the specific storage spaces.

The output circuit 230 may generate an output signal by reading a value stored in the time-varying device. The output signal may be a digital signal representing the magnitude of the value stored in the time-varying device. The output signal may be a digital signal having one or more bits. For example, the output signal may be 0 or 1, and, when the output signal is 0, this indicates that the value stored in the time-varying device is smaller than a predetermined value, and, when the output signal is 1, this indicates that the value stored in the time-varying device is greater than or equal to the predetermined value. Alternatively, the output signal may be 00, 01, 10, or 11, and a larger output signal may represent a larger value being stored in the time-varying device.

The predetermined value may be changed according to an electronic device equipped with an electronic circuit. The predetermined value may be changed according to the type and/or specification of a processor, memory, or application of the electronic device. Alternatively, the predetermined value may be changed according to a user's settings.

The output circuit 230 may include a read-out circuit for reading the value stored in the time-varying device. The read-out circuit may be configured to read out the value stored in the time-varying device as a digital signal. For example, the read-out circuit may be configured to read out 0 when the value stored in the time-varying device is less than the predetermined value, and read out 1 when the value stored in the time-varying device is greater than or equal to the predetermined value.

Alternatively, the read-out circuit may be configured to read out the value stored in the time-varying device as an analog signal. In this case, compared to a case where the value stored in the time-varying device is read out as a digital signal, the value stored in the time-varying device may be read out with higher precision. In this case, the output circuit 230 may include at least one of an analog to digital converter (ADC) and a time-to-digital converter (TDC) for converting an analog signal into a digital signal. However, embodiments are not limited thereto.

In response to an event of requiring replacement of a storage space of a memory, the output circuit 230 may generate an output signal by reading a value stored in a time-varying device corresponding to the storage space related to the event.

Alternatively, the output circuit 230 may generate an output signal by reading values stored in two or more time-varying devices, in response to an event in which a storage space for replacement in the memory needs to be determined. The event in which the storage space for replacement in the memory needs to be determined may be related to two or more storage spaces, and the output circuit 230 may read the values stored in two or more time-varying devices corresponding to the two or more storage spaces related to the event.

The controller 240 may be configured to determine the storage space for replacement in the memory, based on the output signal received from the output circuit 230. When an event for the storage space does not occur, a value stored in the time-varying device may decrease. When the event for the storage space occurs, a value stored in the time-varying device may be increased by the input signal. Therefore, because it may be estimated from the value stored in the time-varying device whether the event has occurred in the storage space, the storage space for replacement in the memory may be determined, based on the output signal.

Because the output signal represents the value stored in the time-varying device, the controller 240 may analyze the value stored in the time-varying device, based on the output signal.

When the value stored in the time-varying device is less than the predetermined value, the controller 240 may determine a storage space corresponding to the time-varying device as the storage space for replacement. For example, the controller 240 may determine that the value stored in the time-varying device is less than the predetermined value, when the output signal is 0, and may determine a storage space corresponding to the time-varying device as the storage space for replacement. Alternatively, the controller 240 may determine that the value stored in the time-varying device is not less than the predetermined value, when the output signal is 1, and may not determine the storage space corresponding to the time-varying device as the storage space for replacement.

The controller 240 may determine the storage space for replacement in the memory, by comparing the values stored in the time-varying devices, based on the output signal. The controller 240 may determine, as the storage space for replacement, a storage space corresponding to a time-varying device storing the smallest value among the time-varying devices. For example, when output signals generated by reading values stored in four time-varying devices are 00, 01, 01, and 10, the controller 240 may determine, as the storage space for replacement, a storage space corresponding to a time-varying device from which 00 is read as an output signal.

Alternatively, the controller 240 may determine the storage space for replacement in the memory, by comparing the values stored in the time-varying devices with the predetermined value, based on the output signal. The controller 240 may determine, as the storage space for replacement, a storage space corresponding to a time-varying device storing a value less than the predetermined value among the time-varying devices. For example, when the output signals generated by reading the values stored in the four time-varying devices are 00, 01, 01, and 10 and the predetermined value is 01, the controller 240 may determine, as the storage space for replacement, a storage space corresponding to a time-varying device from which 00 is read as an output signal.

Among time-varying devices having the same output signals, the controller 240 may arbitrarily select one time-varying device, and may determine a storage space corresponding to the selected time-varying device as the storage space for replacement in the memory. For example, when output signals generated by reading values stored in three time-varying devices are 0, 0, and 1, the controller 240 may determine, as the storage space for replacement, a storage space corresponding to one of two time-varying devices from which 0 is read as an output signal.

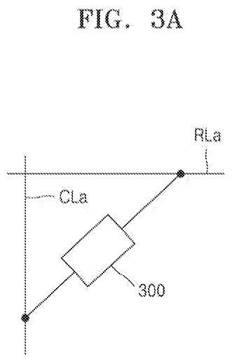

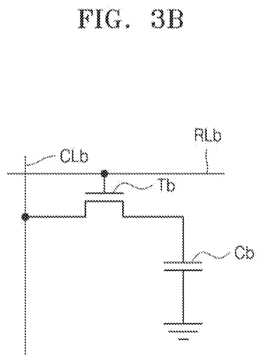

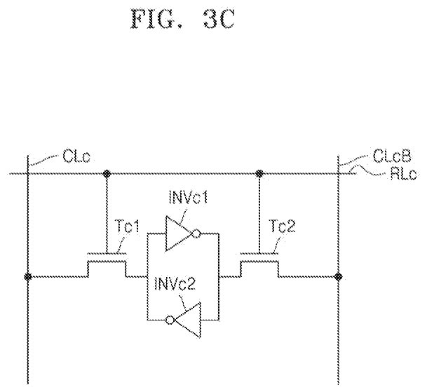

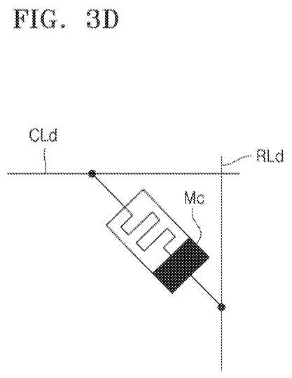

FIG. 3A is a circuit diagram of a time-varying device 300 according to an embodiment.

A time-varying circuit includes a plurality of time-varying devices, and FIG. 3A shows one time-varying device 300 among the plurality of time-varying devices.

In the time-varying device 300, a stored value changes over time. The value stored in the time-varying device 300 may decrease with time according to a retention feature of the time-varying device 300.

The time-varying device 300 may store a value in the form of an electric charge. To this end, the time-varying device 300 may include a reservoir for storing an electric charge. According to a retention feature of the time-varying device 300, electric charges stored in the reservoir may be discharged over time. Accordingly, the value stored in the time-varying device 300 may also decrease.

Alternatively, the time-varying device 300 may store a value in the form of a voltage. A magnitude of a voltage of a specific node of the time-varying device 300 may represent the value stored in the time-varying device 300. When a voltage lower than a retention voltage or no voltage is provided to the time-varying device 300, the magnitude of the voltage of the specific node of the time-varying device 300 may decrease according to a retention time of the time-varying device 300. Accordingly, the value stored in the time-varying device 300 may also decrease.

Alternatively, the time-varying device 300 may store a value in the form of conductance. To this end, the time-varying device 300 may include a resistive device whose conductance changes according to voltage. A magnitude of the conductance of the resistive device may represent the value stored in the time-varying device 300. The resistive device may have a retention feature in which conductance decreases with time. Accordingly, the value stored in the time-varying device 300 may also decrease.

The time-varying device 300 may be electrically connected to a row line RLa and a column line CLa. At least one of the row line RLa and the column line CLa may be used to provide an input signal to the time-varying device 300 or to read a value stored in the time-varying device 300. In FIG. 3A, the time-varying device 300 is connected to one row line RLa and one column line CLa. However, the time-varying device 300 may be connected to a plurality of row lines and a plurality of column lines.

As an input signal is provided through the row line RLa and/or the column line CLa, the value stored in the time-varying device 300 may increase. When the time-varying device 300 stores a value in the form of electric charge, the value stored in the time-varying device 300 may increase as the amount of electric charge is increased by the input signal. Alternatively, when the time-varying device 300 stores a value in the form of voltage, the value stored in the time-varying device 300 may increase as the voltage of the specific node is increased by the input signal. Alternatively, when the time-varying device 300 stores a value in the form of conductance, the conductance of the resistive device increases as the voltage applied to the resistive device is increased by the input signal, and thus the value stored in the time-varying device 300 may increase.

The value stored in the time-varying device 300 may represent a state of a corresponding storage space of the memory. When an event does not occur in the storage space, an input signal is not provided to the time-varying device 300, and thus the value stored in the time-varying device 300 may decrease. When an event occurs in the storage space, an input signal may be applied to the time-varying device 300, and thus the value stored in the time-varying device 300 may increase. Accordingly, as the value stored in the time-varying device 300 decreases, it may be estimated that no event has recently occurred or few events have occurred in the storage space corresponding to the time-varying device 300. As the value stored in the time-varying device 300 increases, it may be estimated that an event has recently occurred or many events have occurred in the storage space corresponding to the time-varying device 300. Therefore, it may be estimated from the value stored in the time-varying device 300 how recently an event has occurred or how many events have occurred in the corresponding storage space.

As a change in the value stored in the time-varying device according to the retention feature reflects the fact that no event for the storage space has occurred, there is no need to apply energy to the time-varying device in order to indicate a state in which no event for the storage space has occurred, so that energy efficiency may be obtained.

FIGS. 3B through 3D illustrate time-varying devices according to embodiments. FIGS. 3B through 3D show implementation examples of the time-varying device, and implementation examples of the time-varying device are not limited by FIGS. 3B through 3D.

Referring to FIG. 3B, a time-varying device may include DRAM. The DRAM may include a transistor Tb and a capacitor Cb. The capacitor Cb, which is a storage, may store electric charge. The amount of electric charge stored in the capacitor Cb may represent a value stored in the time-varying device. According to an input signal applied through a row line RLb and/or a column line CLb, electric charge may be stored in the capacitor Cb or the amount of electric charge in the capacitor Cb may be read.

Referring to FIG. 3C, a time-varying device may include SRAM. The SRAM may be a 6T (six transistors) SRAM. The SRAM may include a first inverter INVc1 having 2T (two transistors), a second inverter INVc2 having 2T, and transistors Tc1 and Tc2 connected to the first and second inverters INVc1 and INVc2. The voltage of an output node of the first inverter INVc1 or an output node of the second inverter INVc2 may represent a value stored in the time-varying device. According to an input signal applied through a row line RLc, a column line CLc, or a column line bar CLcB, a voltage may be applied to the output node of the first inverter INVc1 or the output node of the second inverter INVc2, or the voltage of the output node of the first inverter INVc1 or the output node of the second inverter INVc2 may be read.

Referring to FIG. 3D, the time-varying device may include a memristor Mc that is a resistive device whose conductance changes according to voltage. The conductance of the memristor Mc may represent a value stored in the time-varying device. According to an input signal applied through a row line RLd or a column line CLd, the conductance of the memristor Mc may increase or the conductance of the memristor Mc may be read.

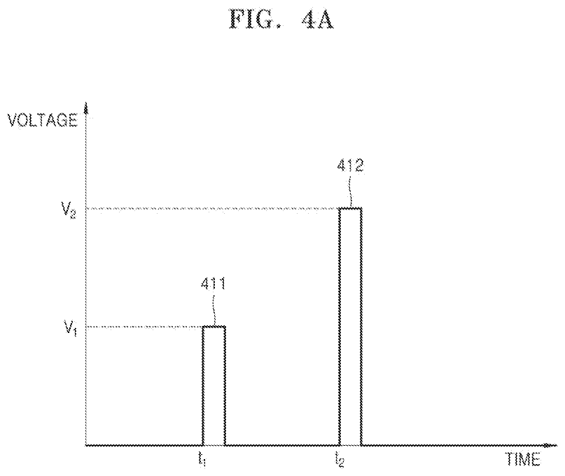

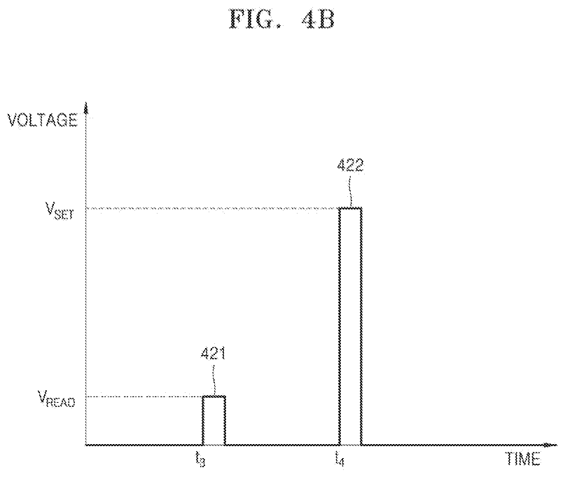

FIG. 4A is a graph showing an input signal according to an embodiment.

The input signal provided to a time-varying circuit may be a voltage pulse signal. The input signal may be generated in response to the event for the memory. The input signal may be provided to a time-varying device corresponding to a storage space of the memory related to the event. The input signal may be applied to the time-varying device through a row line or a column line. As the input signal is applied, the value stored in the time-varying device may change.

Input signals having different magnitudes may be generated according to the type of event. For example, in response to a first event, a first input signal 411 having a magnitude of V₁ at t₁ may be generated, and, in response to a second event having a different type from the first event, a second input signal 412 having a magnitude of V₂ at t₂ may be generated.

Because the second input signal 412 has a larger magnitude than the first input signal 411, the value stored in the time-varying device may be more increased when the second input signal 412 is applied than when the first input signal 411 is applied. Accordingly, by applying input signals having different magnitudes according to the type of event to the time-varying circuit, the value of the time-varying device may be changed by reflecting the type of event.

FIG. 4B is a graph showing an input signal according to an embodiment.

When the event for the memory is an event in which the storage space for replacement in the memory needs to be determined, that is, an event of requiring reading of a value stored in the time-varying device, a first input signal 421 having a magnitude of V_{READ} may be generated. The event in which the storage space for replacement in the memory needs to be determined may include at least one of an event in which a processor requires data not stored in the memory and an event in which a high level memory requires the data not stored in the memory, but embodiments are not limited thereto.

The first input signal 421 may be provided to a time-varying device corresponding to a storage space related to an event. When the first input signal 421 having a magnitude of V_{READ} is provided to the time-varying device, the value stored in the time-varying device may be read by an output circuit.

When the event for the memory is an event in which the storage space for replacement in the memory does not need to be determined, that is, an event of not requiring reading of the value stored in the time-varying device, a second input signal 422 having a magnitude of V_{SET} may be generated. The event in which the storage space for replacement does not need to be determined from the memory may include at least one of an event in which a processor accesses data stored in the memory, an event in which a high level memory accesses the data stored in the memory, and an event of replacing the storage space pre-determined from the memory, but embodiments are not limited thereto. Because the event in which a storage space pre-determined from the memory is replaced involves pre-determination of the storage space and thus does not need determination of the storage space for replacement, the event may be included in an event in which the storage space for replacement in the memory does not need to be determined.

The second input signal 422 may be provided to a time-varying device corresponding to a storage space related to an event. When the second input signal 422 having a magnitude of V_{SET} is provided to the time-varying device, the value stored in the time-varying device may increase.

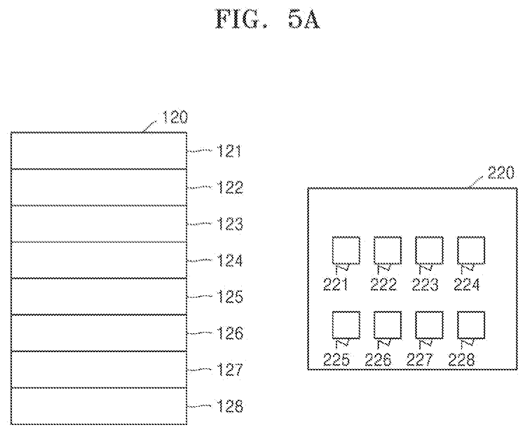

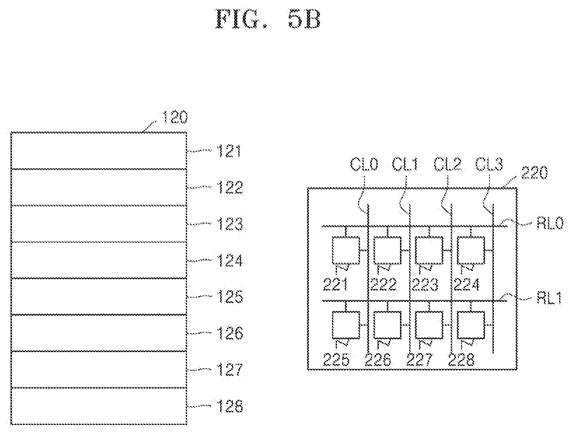

FIG. 5A is a diagram illustrating a correspondence between storage spaces and time-varying devices according to an embodiment;

The memory 120 may include a plurality of storage spaces 121 through 128. The time-varying circuit 220 may include a plurality of time-varying devices 221 through 228. Although eight storage spaces 121 through 128 and eight time-varying devices 221 through 228 are shown in FIG. 5A, the number of storage spaces included in the memory 120 and the number of time-varying devices included in the time-varying circuit 220 are not limited thereto.

The storage space of the memory 120 may be a chunk having a predetermined size. For example, when the memory 120 is a main memory, the storage space of the memory 120 may be a memory block. Alternatively, when the memory 120 is a cache, the storage space of the memory 120 may be a cache line.

The plurality of time-varying devices 221 through 228 may correspond to the plurality of storage spaces 121 through 128. A correspondence between the plurality of time-varying devices 221 through 228 and the plurality of storage spaces 121 through 128 may vary.

One time-varying device may correspond to one storage space. For example, a first time-varying device 221 may correspond to a first storage space 121, and a second time-varying device 222 may correspond to a second storage space 122. In the same way, an eighth time-varying device 228 may correspond to an eighth storage space 128. For example, when an event occurs in the first storage space 121 among the plurality of storage spaces 121 through 128, an input signal may be provided to the first time-varying device 221 among the plurality of time-varying devices 221 through 228. For example, when a value stored in the second time-varying device 222 among the plurality of time-varying devices 221 through 228 is the smallest, the second storage space 122 among the plurality of storage spaces 121 through 128 may be determined as a storage space for replacement.

Alternatively, one time-varying device may correspond to one or more storage spaces. For example, the first time-varying device 221 may correspond to the first and second storage spaces 121 and 122, the second time-varying device 222 may correspond to the third and fourth storage spaces 123 and 124, the third time-varying device 223 may correspond to the fifth through seventh storage spaces 125 through 127, and the fourth time-varying device 224 may correspond to the eighth storage space 128. In this case, when one time-varying device is selected based on the values of the time-varying devices, one of one or more corresponding storage spaces may be determined as a storage space for replacement. For example, when a value stored in the third time-varying device 223 among the plurality of time-varying devices 221 through 228 is the smallest, one of the fifth through seventh storage spaces 125 through 127 corresponding to the third time-varying device 223 may be determined as a storage space for replacement.

Alternatively, one or more time-varying devices may correspond to one storage space. For example, the first and second time-varying devices 221 and 222 may correspond to the fourth storage space 124, the third and fourth time-varying devices 223 and 224 may correspond to the fifth storage space 125, the fifth and sixth time-varying devices 225 and 226 may correspond to the sixth storage space 126, and the seventh and eighth time-varying devices 227 and 228 may correspond to the seventh storage space 127. In this case, even when the first time-varying device 221 among the first and second time-varying devices 221 and 222 malfunctions, replacement of the fourth storage space 124 may be determined based on the second time-varying device 222, and thus a reliable storage space replacement may be made.

According to embodiments, because the number of time-varying devices is proportional to the number of storage spaces, the number of time-varying devices may increase linearly as the size of the memory 120 increases. Accordingly, excellent scalability for the size of the memory 120 may be obtained.

FIG. 5B is a diagram illustrating an operation of changing a value stored in a time-varying device and an operation of reading the value stored in the time-varying device, according to an embodiment.

The operation of changing the value stored in the time-varying device and the operation of reading the value stored in the time-varying device will be described with reference to FIG. 5B. For convenience of description, it is assumed in FIG. 5B that the first through eighth storage spaces 121 through 128 of the memory 120 correspond to the first through eighth time-varying devices 221 through 228 of the time-varying circuit 220 in one-to-one correspondence.

The time-varying circuit 220 may include the plurality of time-varying devices 221 through 228 arranged in an array. In FIG. 5B, the plurality of time-varying devices 221 through 228 are arranged in a two-dimensional (2D) array. However, embodiments are not limited thereto. For example, the plurality of time-varying devices 221 through 228 may be arranged in a one-dimensional (1D) array or a three-dimensional (3D) array.

The time-varying circuit 220 may include a plurality of row lines RL0 and RL1 and a plurality of column lines CL0 through CL3 electrically connected to the plurality of time-varying devices 221 through 228. FIG. 5B shows, according to an embodiment, the first time-varying device 221 connected to the first row line RL0 and the first column line CL0, the second time-varying device 222 connected to the first row line RL0 and the second column line CL1, and, in the same way, the eighth time-varying device 228 connected to the second row line RL1 and the fourth column line CL3.

When an event for the memory 120 occurs, an input signal may be provided to a time-varying device corresponding to a storage space related to the event. For example, an input signal may be provided to the third time-varying device 223 in response to an event of accessing data in the third storage space 123. For example, by applying a voltage pulse of V_{SET} to the first row line RL0 and applying a ground voltage to the third column line CL2, a voltage of V_{SET} may be applied to the third time-varying device 223. In this case, by applying a voltage less than V_{SET} and greater than the ground voltage to the second row line RL1 and the second and fourth column lines CL1 and CL3, an influence of the voltage pulse of V_{SET} applied to the first row line RL0 upon the adjacent time-varying devices of the third time-varying device 223 may be minimized.

The input signal provided to the time-varying device may increase the value stored in the time-varying device. For example, the voltage of VSET applied to the third time-varying device 223 increases the amount of electric charge, a voltage, or a conductance of the third time-varying device 223, thereby increasing the value stored in the third time-varying device 223.

When an event in which a storage space for replacement in the memory needs to be determined occurs, an input signal may be provided to time-varying devices corresponding to storage spaces related to the event. For example, in response to an event of requiring a storage space for replacement to be determined among the first through fourth storage spaces 121 through 124, an input signal may be provided to the first through fourth time-varying devices 221 through 224. For example, a voltage pulse of V_{READ} may be applied to the first row line RL0 connected to the first through fourth time-varying devices 221 through 224. In this case, the first through fourth column lines CL0 through CL3 connected to the first through fourth time-varying devices 221 through 224 may be connected to an output circuit, and values stored in the first through fourth time-varying devices 221 through 224 may be read by the output circuit.

Based on the values read by the output circuit, the storage space for replacement may be determined. For example, when a value stored in the first time-varying device 221 among the first through fourth time-varying devices 221 through 224 is the smallest, the first storage space 121 among the first through fourth storage spaces 121 through 124 may be determined as the storage space for replacement. Alternatively, when a value stored in the second time-varying device 222 among the first through fourth time-varying devices 222 through 224 is less than the predetermined value, the second storage space 122 among the first through fourth storage spaces 122 through 124 may be determined as the storage space for replacement. Alternatively, when values stored in the second and third time-varying devices 222 and 223 among the first through fourth time-varying devices 222 through 224 are less than the predetermined value, one of the second and third storage spaces 122 and 123 may be determined as the storage space for replacement.

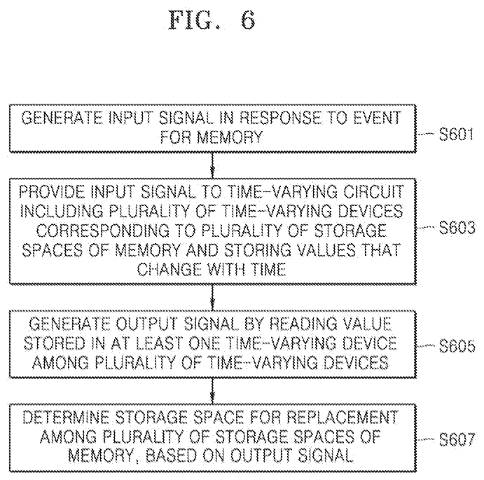

FIG. 6 is a flowchart of a method for memory replacement according to an embodiment.

In operation S601, an input signal is generated in response to an event for a memory.

The event for a memory may be classified into an event in which a storage space for replacement in the memory does not need to be determined, or an event in which a storage space for replacement in the memory needs to be determined.

The input signal may be generated differently according to the type of event. For example, an input signal generated in response to an event in which a storage space for replacement in the memory does not need to be determined may have a greater magnitude than an input signal generated in response to an event in which a storage space for replacement needs to be determined in the memory.

In operation S603, the input signal is provided to a time-varying circuit including a plurality of time-varying devices corresponding to a plurality of storage spaces of the memory and storing values that change with time.

The input signal may be provided to a time-varying device corresponding to a storage space related to the event. When an event occurs in the plurality of storage spaces, the input signal may be provided to the plurality of time-varying devices.

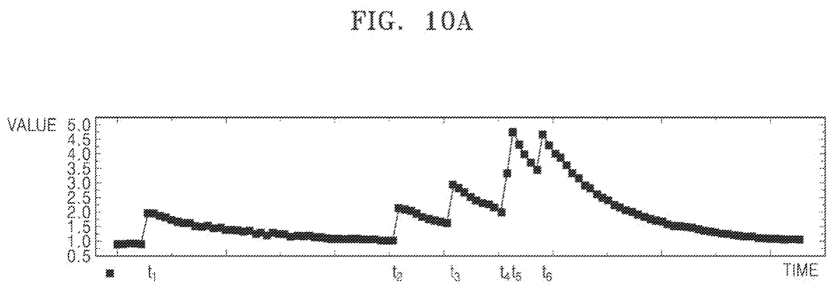

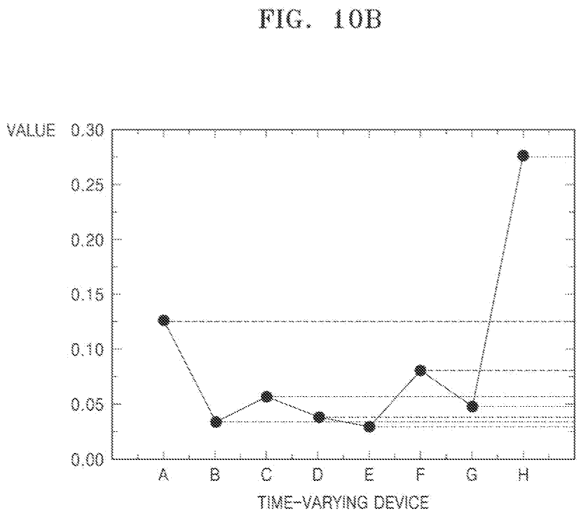

FIG. 10A shows a value stored in a time-varying device according to an embodiment. Referring to FIG. 10A together, a total of 6 input signals are applied to the time-varying device at t₁, t₂, t₃, t₄, t₅, and t₆. As the input signal is applied at t₁, the value stored in the time-varying device increases, and, according to the retention feature of the time-varying device, the value stored in the time-varying device decreases until the input signal is applied at t₂. As input signals are applied at t₂, t₃, t₄, t₅, and t₆, the value stored in the time-varying device increases. In particular, as input signals are successively applied at t₄ and t₅, the stored value of the time-varying device greatly increases. In this way, the more recently the input signal has been applied to the time-varying device and the more input signals have been applied to the time-varying device, the higher the value of the time-varying device is. Therefore, it may be estimated from the value stored in the time-varying device how recently an event has occurred or how many events have occurred in the corresponding storage space.

In operation S605, an output signal is generated by reading a value stored in at least one time-varying device among a plurality of time-varying devices.

The output signal may be generated in response to an event in which the storage space for replacement in the memory needs to be determined. The output signal may be generated by reading a value stored in a time-varying device corresponding to a storage space related to the event.

In operation S607, the storage space for replacement is determined among the plurality of storage spaces of the memory, based on the output signal.

Because the output signal represents the value stored in the time-varying device, the value stored in the time-varying device may be analyzed based on the output signal.

When the value stored in the time-varying device is less than the predetermined value, it may be estimated that no event has recently occurred in the storage space corresponding to the time-varying device. On the other hand, when the value stored in the time-varying device is equal to or greater than the predetermined value, it may be estimated that an event has recently occurred in the storage space corresponding to the time-varying device. According to time locality, an event is highly likely to occur again in a storage space in which an event has recently occurred, and thus a storage space corresponding to a time-varying device having a stored value smaller than the predetermined value may be determined as the storage space for replacement.

Values stored in two or more time-varying devices may be analyzed to determine the storage space for replacement among the two or more storage spaces.

A storage space corresponding to a time-varying device storing a value less than the predetermined value among the two or more time-varying devices may be determined as the storage space for replacement. When there are a plurality of time-varying devices storing values smaller than the predetermined value, one of the plurality of time-varying devices may be randomly determined.

Alternatively, a storage space corresponding to a time-varying device storing a smallest value among the two or more time-varying devices may be determined as the storage space for replacement. When there are a plurality of time-varying devices storing smallest values, one of the plurality of time-varying devices may be randomly determined.

FIG. 10B shows values stored in time-varying devices A through H according to an embodiment. Referring to FIG. 10B together, a value stored in the time-varying device A is about 0.13, a value stored in the time-varying device B is about 0.04, a value stored in the time-varying device C is about 0.07, a value stored in the time-varying device D is about 0.05, a value stored in the time-varying device E is about 0.03, a value stored in the time-varying device F is about 0.08, a value stored in the time-varying device G is about 0.06, and a value stored in the time-varying device H is about 0.28. For example, when the predetermined value is 0.04, a storage space corresponding to the time-varying device E storing a value less than the predetermined value may be determined as the storage space for replacement. Alternatively, when the predetermined value is 0.05, one of storage spaces corresponding to the time-varying devices B and E storing values less than the predetermined value may be determined as the storage space for replacement. Alternatively, a storage space corresponding to the time-varying device E storing the smallest value may be determined as the storage space for replacement.

In the disclosure, the state of a storage space corresponds to a value stored in a time-varying device. When no event occurs in the storage space, the value of the time-varying device naturally decreases according to the retention feature. When an event occurs in the storage space, the value stored in the time-varying device may be increased by an input signal. In the disclosure, the number of time-varying devices is proportional to the number of storage spaces.

These features of the disclosure make it possible to analyze all storage spaces that are candidates for replacement, simply by analyzing the values stored in the corresponding time-varying devices. Even when the size of the memory increases, the number of time-varying devices only increases in proportion to an increase in the number of storage spaces, and thus all storage spaces that are candidates for replacement may be analyzed.

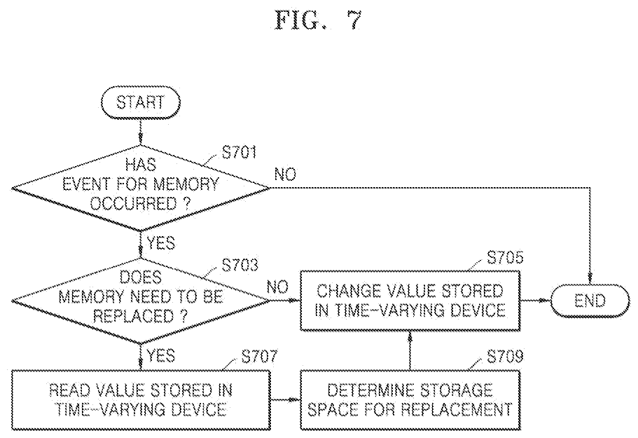

FIG. 7 is a flowchart of an operation method of an electronic circuit for memory replacement, according to an embodiment.

In operation S701, it may be determined whether an event for a memory has occurred.

The determination as to whether the event for the memory has occurred may be made every clock cycle that is predetermined. The clock cycle may be determined to be proportional to a clock cycle of a processor. When the event for the memory has occurred, the method proceeds to operation S703, and, when the event for the memory has not occurred, a current cycle is terminated, and operation S701 is re-executed in a next cycle.

In operation S703, it is determined whether the event for the memory is an event in which a storage space for replacement in the memory needs to be determined.

When the event for the memory is an event in which a processor accesses data stored in the memory, an event in which a high level memory accesses the data stored in the memory, or an event of replacing the storage space pre-determined from the memory is replaced, the event for the memory may be determined to be an event in which the storage space for replacement in the memory does not need to be determined. In this case, the method proceeds to operation S705.

When the event for the memory is an event in which the processor needs data not stored in the memory or an event in which the high level memory needs the data not stored in the memory, the event for the memory may be determined to be an event in which the storage space for replacement in the memory needs to be determined. In this case, the method proceeds to operation S707.

In operation S705, the value stored in the time-varying device is changed.

The value stored in the time-varying device may be changed by applying an input signal to a time-varying device corresponding to a storage space related to the event. As the input signal is applied, the value stored in the time-varying device may increase.

In operation S707, values stored in time-varying devices are read.

The value stored in the time-varying device may increase in operation S705 or may decrease according to the retention feature. The values stored in the time-varying devices may represent states of corresponding storage spaces. To determine the storage space for replacement, values stored in time-varying devices corresponding to storage spaces related to the event may be read.

In operation S709, the storage space for replacement is determined.

Based on the values stored in the time-varying devices, the storage space for replacement may be determined from among a plurality of storage spaces. For example, a storage space corresponding to a time-varying device having a smaller value than the predetermined value may be determined as the storage space for replacement. Alternatively, a storage space corresponding to a time-varying device having the smallest value may be determined as the storage space for replacement.

The storage space determined in operation S709 may be replaced. The replacement of the storage space determined in operation S709 corresponds to an event of replacing the storage space pre-determined from the memory. Accordingly, when the storage space determined in operation S709 is replaced, the method proceeds to operation S705 to change the value stored in the time-varying device corresponding to the replaced storage space.

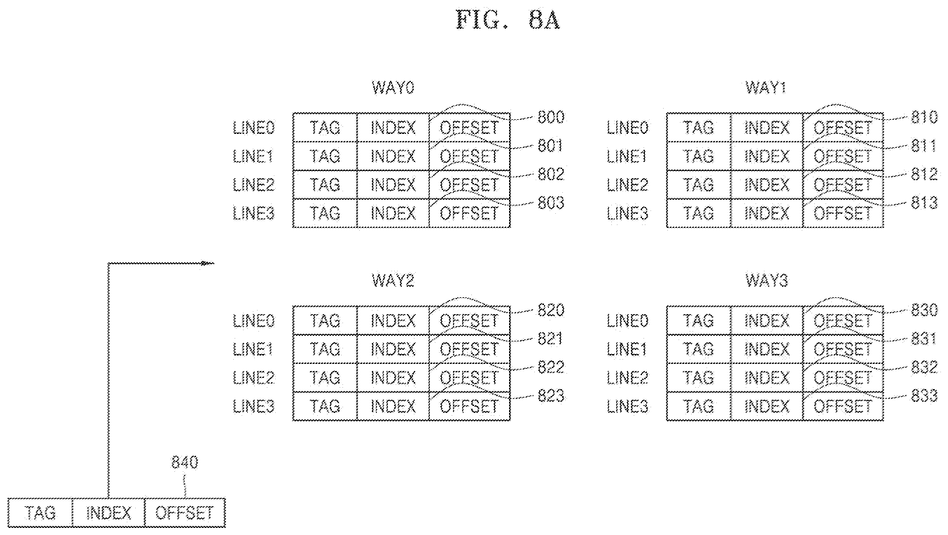

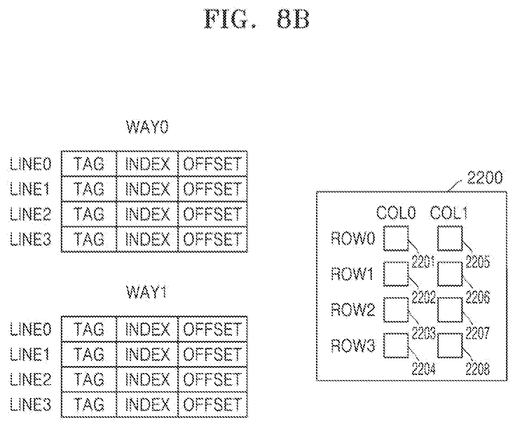

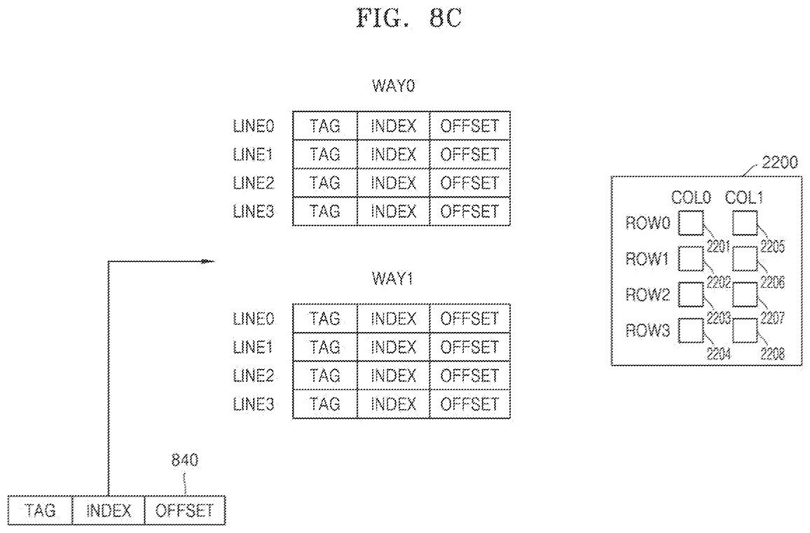

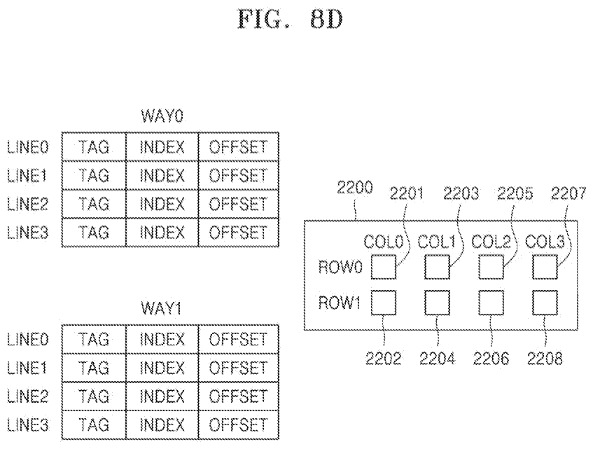

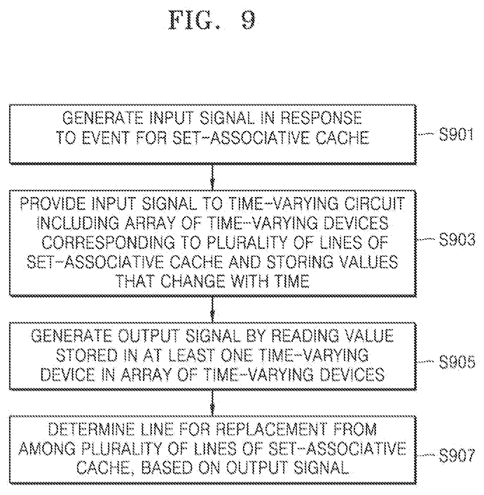

The methods and electronic circuits for memory replacement described with reference to the above embodiments may be used to replace various types of memories. A method for replacing a set-associative cache, which is one of various types of memories, will now be described with reference to FIGS. 8A through 9.

FIG. 8A is a diagram illustrating an address and a set-associative cache according to an embodiment.

FIG. 8A shows a set-associative cache having an address mapping scheme of set-associative mapping. For convenience of explanation, it is assumed that the set-associative cache is a 4-way set-associative cache in which each way has 4 lines.

Each line in the set-associative cache may include a tag field, an index field, and an offset field. The same lines in the four ways may have the same indices. For example, in a set-associative cache having a 2-bit index field, indices 800, 810, 820, and 830 of respective first lines LINE0 of the four ways may be 00, indices 801, 811, 821, and 831 of respective second lines LINE1 of the four ways may be 01, indices 802, 812, 822, and 832 of respective third lines LINE2 of the four ways may be 10, and indices 803, 813, 823, and 833 of respective fourth lines LINE3 of the four ways may be 11.

In set-associative mapping, data 840 may be stored in the way of one of the lines having the same indices. For example, when the index of the data 840 is 00, the data 840 may be stored in one of the first line LINE0 of the first way WAY0, the first line LINE0 of the second way WAY1, the third line LINE0 of the third way WAY2, and the first line LINE0 of the fourth way WAY3.

FIG. 8B is a diagram illustrating a correspondence between a set-associative cache and time-varying elements according to an embodiment;

For convenience of explanation, it is assumed that the set-associative cache is a 2-way set-associative cache in which each way has 4 lines.

In time-varying devices 2201 through 2208 arranged in an array, a way of the set-associative cache may correspond to a column of an array 2200 of time-varying devices, and a line of the set-associative cache may correspond to a row of the array 2200 of time-varying devices. For example, the first way WAY0 may correspond to a first column COL0, and the second way WAY1 may correspond to a second column COL1. The first line LINE0 may correspond to a first row ROW0, the second line LINE1 may correspond to a second row ROW1, the third line LINE2 may correspond to a third row ROW2, and the fourth line LINE3 may correspond to a fourth row ROW3.

A line of the set-associative cache may correspond to a time-varying device. For example, the first through fourth lines LINE0 through LINE3 of the first way WAY0 may correspond to the time-varying devices 2201 through 2204 of a first column COL0, respectively, and the first through fourth lines LINE0 through LINE3 of the second way WAY1 may correspond to the time-varying devices 2205 through 2208 of a second column COL1, respectively.

In response to an event for the set-associative cache, an input signal may be provided to the array 2200 of time-varying devices. An input signal may be provided to a time-varying device corresponding to a line related to the event among the time-varying devices 2201 through 2208. For example, in response to an event in which the processor accesses the first line LINE0 of the first way WAY0, the input signal may be provided to the first time-varying device 2201 corresponding to the first line LINE0 of the first way WAY0.

To provide the input signal to the time-varying device corresponding to the line related to the event, a row and column of the array 2200 of time-varying devices may be selected based on the index and way of the line. In more detail, a row corresponding to the index of the line may be selected, and a column corresponding to the way of the line may be selected. For example, when the line related to the event is the first line LINE0 of the first way WAY0, the first column COL0 corresponding to the first way WAY0 may be selected, and the first row ROW0 corresponding to index 00 may be selected. Accordingly, the first time-varying device 2201 of the first row ROW0 and the first column COL0 corresponding to the first line LINE0 of the first way WAY0 may be selected.

FIG. 8C is a diagram illustrating replacement of the lines of a set-associative cache according to an embodiment.

An event in which a line of the set-association cache needs to be replaced is assumed in order to store the data 840 in the set-associative cache. Lines related to the event in the set-associative cache may be lines having the same indices as the data 840. For example, when the index of the data 840 is 11, the lines related to the event may be the fourth line LINE3 of the first way WAY0 and the fourth line LINE3 of the second way WAY1.

A line for replacement in the set-associative cache may be determined based on values stored in the time-varying devices 2201 through 2208. In detail, the line for replacement in the set-associative cache may be determined based on values stored in time-varying devices corresponding to the lines related to the event. For example, the line for replacement in the set-associative cache may be determined based on the values stored in the fourth time-varying device 2204 and the eighth time-varying device 2208 corresponding to the fourth line LINE3 of the first way WAY0 and the fourth line LINE3 of the second way WAY1 related to the event.

Time-varying devices corresponding to the lines related to the event may be selected based on the ways and indices of the lines related to the event. For example, the fourth time-varying device 2204 may be selected by selecting the first column COL0 corresponding to the first way WAY0 and selecting the fourth row ROW3 corresponding to index 11. The eighth time-varying device 2208 may be selected by selecting the second column COL1 corresponding to the second way WAY1 and selecting the fourth row ROW3 corresponding to index 11.

Alternatively, time-varying devices corresponding to the lines related to the event may be selected based on the indices of the lines related to the event. For example, by selecting the fourth row ROW3 corresponding to the indices 11 of the respective fourth lines LINE3 of the first and second ways WAY0 and WAY1, the fourth and eighth time-varying devices 2204 and 2208 may be selected.

An output signal may be generated by reading values stored in the time-varying devices corresponding to the lines related to the event. For example, an output signal may be generated by reading values stored in the fourth and eighth time-varying devices 2204 and 2208 corresponding to the respective fourth lines LINE3 of the first and second ways WAY0 and WAY1.

Based on the output signal, the line for replacement may be determined based on the values stored in the time-varying devices. For example, when the value stored in the fourth time-varying device 2204 is less than the value stored in the eighth time-varying device 2208, the fourth line LINE3 of the first way WAY0 corresponding to the fourth time-varying device 2204 may be determined as the line for replacement. Accordingly, the data 840 may be stored in the fourth line LINE3 of the first way WAY0. Alternatively, when the value stored in the fourth time-varying device 2204 is less than a predetermined value, the data 840 may be stored in the fourth line LINE3 of the first way WAY0. Alternatively, when the value stored in the fourth time-varying device 2204 is equal to the value stored in the eighth time-varying device 2208, the data 840 may be stored in one of the fourth line LINE3 of the first way WAY0 and the fourth line LINE3 of the second way WAY1.

FIG. 8D is a diagram illustrating a correspondence between a set-associative cache and time-varying devices according to an embodiment;

In set-associative mapping, data is stored in the way of one of the lines having the same indices. In set-associative mapping, the number of rows in the array 2200 of time-varying devices may be equal to or less than the number of lines in the set-associative cache in order to determine a way that is to store data. The number of columns of the array 2200 of time-varying devices may be greater than the number of ways of the set-associative cache. Accordingly, because a method and electronic circuit for memory replacement according to the technical spirit of the disclosure may be implemented with at least as many time-varying devices as the number of ways of the set-associative cache, excellent scalability may be obtained.

When the number of rows of the array 2200 of time-varying devices is less than the number of lines of the set-associative cache, a plurality of lines of the set-associative cache may correspond to one row of the array 2200 of time-varying devices. For example, the first line LINE0 and the third line LINE2 of the first way WAY0 may correspond to a first row ROW0, the first line LINE0 and the third line LINE2 of the second way WAY1 may correspond to the first row ROW0, the second line LINE1 and the fourth line LINE3 of the first way WAY0 may correspond to a second row ROW1, and the second line LINE1 and the fourth line LINE3 of the second way WAY1 may correspond to the second row ROW1.

When the number of columns of the array 2200 of time-varying devices is greater than the number of ways of the set-associative cache, one way of the set-associative cache may correspond to a plurality of columns of the array 2200 of time-varying devices. For example, the first way WAY0 may correspond to a first column COL0 and a second column COL1, and the second way WAY1 may correspond to a third column COL2 and a fourth column COL3.

When the number of rows of the array 2200 of time-varying devices is less than the number of lines of the set-associative cache, an output signal may be generated by selectively reading specific columns from the array 2200 of time-varying devices. The specific columns may be determined based on the index of data to be stored in the set-associative cache. For example, when the index of the data is 00 or 01, the first column COL0 and the third column COL2 may be selectively read. Alternatively, when the index of the data is 10 or 11, the second column COL1 and the fourth column COL3 may be selectively read. For example, for data having an index of 11, the output signal may be generated by reading values stored in the fourth time-varying device 2204, which is a time-varying device of the second column COL1 of the second row ROW1, and the eighth time-varying device 2208, which is a time-varying device of the fourth column COL3 of the second row ROW1.

FIG. 9 is a flowchart of a method for replacing a set-associative cache, according to an embodiment.

In operation S901, an input signal is generated in response to an event for the set-associative cache.

The event for the set-associative cache may be classified into an event in which a line for replacement in the set-associative cache does not need to be determined, or an event in which the line for replacement in the set-associative cache needs to be determined. For example, the event in which a line for replacement in the set-associative cache does not need to be determined may include, but is not limited to, at least one of an event in which a processor accesses data stored in the set-associative cache, an event in which a high level memory accesses the data stored in the set-associative cache, and an event of replacing a line pre-determined in the set-associative cache. For example, the event in which the line for replacement in the set-associative cache needs to be determined may include, but is not limited to, at least one of an event in which a processor needs data not stored in the set-associative cache and an event in which a high level memory needs the data not stored in the set-associative cache.

The input signal may be generated differently according to the type of event. For example, an input signal generated in response to an event in which a line for replacement in the set-associative cache does not need to be determined may have a greater magnitude than an input signal generated in response to an event in which a line for replacement needs to be determined in the set-associative cache.

In operation S903, the input signal is provided to a time-varying circuit including an array of time-varying devices corresponding to a plurality of lines of the set-associative cache and storing values that change with time.

The input signal may be provided to a time-varying device corresponding to a line related to the event.

A way of the set-associative cache may correspond to a column of time-varying devices, and an index of the set-associative cache may correspond to a row of time-varying devices. Accordingly, in order to provide the input signal to a time-varying device corresponding to a line, a time-varying device located in a column corresponding to a way of the line and a row corresponding to an index of the line may be selected.

In operation S905, an output signal is generated by reading a value stored in at least one time-varying device in an array of time-varying devices.

The output signal may be generated in response to an event in which the line for replacement in the set-associative cache needs to be determined.

The output signal may be generated by reading values stored in time-varying devices corresponding to lines related to the event. When the event is related to lines having a specific index, the output signal may be generated by reading values stored in time-varying devices of a row corresponding to the specific index.

In operation S907, the line for replacement is determined from among a plurality of lines of the set-associative cache, based on the output signal.

Because the output signal represents the value stored in the time-varying device, the value stored in the time-varying device may be analyzed based on the output signal. Values stored in two or more time-varying devices may be analyzed to determine the line for replacement among the two or more lines.

A line corresponding to a time-varying device storing a value less than a predetermined value among the two or more time-varying devices may be determined as the line for replacement. When there are a plurality of time-varying devices storing values smaller than the predetermined value, one of the plurality of time-varying devices may be randomly determined.

Alternatively, a line corresponding to a time-varying device storing a smallest value among the two or more time-varying devices may be determined as the line for replacement. When there are a plurality of time-varying devices storing smallest values, one of the plurality of time-varying devices may be randomly determined.

According to the method and electronic circuit for memory replacement according to the technical spirit of the disclosure, a value stored in a time-varying device represents a state of a corresponding storage space.

Therefore, replacement of the corresponding storage space may be determined by reading the value stored in the time-varying device.

As a change in the value stored in the time-varying device according to the retention feature reflects the fact that no event for the storage space has occurred, there is no need to apply energy to the time-varying device in order to indicate a state in which no event for the storage space has occurred, so that energy efficiency may be obtained.

In addition, because only the number of time-varying devices needs to be increased in response to an increase in the size of the memory, excellent scalability may be obtained.

Moreover, because a method and electronic circuit for memory replacement according to the technical spirit of the disclosure may be implemented with at least as many time-varying devices as the number of ways of the set-associative cache, excellent scalability may be obtained.

Effects that may be obtained in embodiments of the disclosure are not limited to the above-stated effects, and other effects not stated may be clearly derived and understood from the following description by one of ordinary skill in the art to which embodiments of the disclosure pertain. In other words, unintended effects associated with the reduction of one or more embodiments of the disclosure into practice may also be derived from one or more embodiments by one of ordinary skill in the art.

While the disclosure has been particularly shown and described with reference to exemplary embodiments thereof, it will be understood that various changes in form and details may be made therein without departing from the spirit and scope of the disclosure. Thus, the above-described embodiments should be considered in descriptive sense only and not for purposes of limitation. For example, each component described as a single type may be implemented in a distributed manner, and similarly, components described as being distributed may be implemented in a combined form.

The scope of the disclosure is indicated by the scope of the claims to be described later rather than the above detailed description, and all changes or modified forms derived from the meaning and scope of the claims and the concept of equivalents thereof should be interpreted as being included in the scope of the disclosure.

What is claimed is:

1. A method for memory replacement, the method comprising:
generating an input signal in response to an event for a memory;
providing the input signal to a time-varying circuit including a plurality of time-varying devices that correspond to a plurality of storage spaces of the memory and store values that change with time;
generating an output signal by reading a value stored in at least one time-varying device among the plurality of time-varying devices; and
determining a storage space for replacement from among the plurality of storage spaces of the memory, based on the output signal.

2. The method of claim 1, wherein the generating of the input signal comprises generating a different input signal according to the type of the event for the memory.

3. The method of claim 1, wherein the generating of the input signal comprises:
generating a first input signal when the event for the memory is an event in which a storage space for replacement in the memory does not need to be determined; and
generating a second input signal when the event for the memory is an event in which a storage space for replacement in the memory needs to be determined.

4. The method of claim 1, wherein the providing of the input signal to the time-varying circuit comprises providing the input signal to the time-varying circuit such that the value stored in at least one time-varying device among the plurality of time-varying devices is changed.

5. The method of claim 1, wherein the providing of the input signal to the time-varying circuit comprises providing the input signal to the time-varying circuit such that the value stored in at least one time-varying device among the plurality of time-varying devices is read.

6. The method of claim 1, wherein the providing of the input signal to the time-varying circuit comprises providing the input signal to a time-varying device corresponding to a storage space related to the event among the plurality of storage spaces of the memory, from among the plurality of time-varying devices.

7. The method of claim 1, wherein the generating of the output signal comprises generating the output signal by reading values stored in two or more time-varying devices corresponding to two or more storage spaces related to the event among the plurality of storage spaces of the memory, from among the plurality of time-varying devices.

8. The method of claim 7, wherein the determining of the storage space for replacement comprises:
selecting one time-varying device from among the two or more time-varying devices by analyzing, based on the output signal, the values stored in the two or more time-varying devices; and
determining a storage space corresponding to the selected time-varying device, from among the two or more storage spaces, as the storage space for replacement.

9. The method of claim 8, wherein the selecting of the one time-varying device from among the two or more time-varying devices comprises selecting one time-varying device storing a value less than a predetermined value, from among the two or more time-varying devices, based on the output signal.

10. The method of claim 8, wherein the selecting of the one time-varying device from among the two or more time-varying device comprises selecting one time-varying device storing a smallest value, from among the two or more time-varying devices, based on the output signal.

11. An electronic circuit for memory replacement, the electronic circuit comprising:
an input circuit configured to generate an input signal in response to an event for a memory;
a time-varying circuit configured to receive the input signal, and comprising a plurality of time-varying devices that correspond to a plurality of storage spaces of the memory and store values that change with time;
an output circuit configured to generate an output signal by reading a value stored in at least one time-varying device among the plurality of time-varying devices; and
a controller configured to determine a storage space for replacement from among the plurality of storage spaces of the memory, based on the output signal.

12. The electronic circuit of claim 11, wherein the memory comprises at least one of a register, a cache memory, and a main memory.

13. The electronic circuit of claim 11, wherein each of the plurality of time-varying devices comprises at least one of a memristor, dynamic random-access memory (DRAM), and static random-access memory (SRAM).

14. The electronic circuit of claim 11, wherein each of the plurality of time-varying devices is configured to increase a stored value as an input signal generated in response to an event in which a storage space for replacement in the memory needs to be determined is provided.

15. A method for replacing a set-associative cache, the method comprising:
generating an input signal in response to an event for the set-associative cache;
providing the input signal to a time-varying circuit including an array of time-varying devices that correspond to a plurality of lines of the set-associative cache and store values that change with time;
generating an output signal by reading a value stored in at least one time-varying device in the array of time-varying devices; and
determining a line for replacement from among the plurality of lines of the set-associative cache, based on the output signal.

16. The method of claim 15, wherein the providing of the input signal to the time-varying circuit comprises:
selecting a row and a column of the array of time-varying devices, based on an index and a way of a line related to the event from among the plurality of lines; and
providing the input signal to a time-varying device in the selected row and the selected column in the array of time-varying devices.

17. The method of claim 16, wherein the selecting of the row and the column of the array of time-varying devices comprises:
selecting a row of the array of time-varying devices corresponding to the index of the line related to the event; and
selecting a column of the array of time-varying devices corresponding to the way of the line related to the event.

18. The method of claim 15, wherein the generating of the output signal comprises generating the output signal by reading values stored in time-varying devices in one row in the array of time-varying devices.

19. The method of claim 15, wherein the generating of the output signal comprises:
selecting a row of the array of time-varying devices, based on an index of lines related to the event from among the plurality of lines; and
generating the output signal by reading values stored in time-varying devices in the selected row in the array of time-varying devices.

20. The method of claim 19, wherein the determining of the line for replacement comprises:
selecting one time-varying device from among time-varying devices in the selected row by analyzing, based on the output signal, values stored in the time-varying devices in the selected row; and
determining, as the line for replacement, a line of a way corresponding to a column of the selected time-varying device from among the lines related to the event.
